(19) United States
(12) Patent Application Publication
(10) Pub. No.: US 2009/0137099 A1
(43) Pub. Date: May 28, 2009

(54) MBE DEVICE AND METHOD FOR THE OPERATION THEREOF

(75) Inventors: Hans-Peter Schonherr, Berlin (DE); Albrecht Fischer, Lochgau (DE)

Correspondence Address: SCHNADER HARRISON SEGAL & LEWIS, LLP, 1600 MARKET STREET, SUITE 3600, PHILADELPHIA, PA, 19103, US

(73) Assignees: FORSCHUNGSVERBUND BERLIN E.V., Berlin (DE); CREATEC FISCHER & CO. GMBH, Erligheim (DE)

(21) Appl. No.: 12/270,420

(22) Filed: Nov. 13, 2008

(30) Foreign Application Priority Data
Nov. 16, 2007 (DE) DE102007054851.8

(51) Int. Cl. H01L 21/20; C23C 16/54

(52) U.S. Cl. 438/478; 118/715; 257/E21.09

(57) ABSTRACT

A molecular beam epitaxy (MBE) device (100) which is designed for the reactive deposition of a group III nitride compound semiconductor comprises a vacuum chamber (10) which comprises at least one molecular beam source (11) and at least one injector (12) designed to inject ammonia into the vacuum chamber (10), a first cold trap device (20) comprising at least one cold trap (21, 22) designed to condense excess ammonia, a pump device (30) comprising at least one pump (31, 33, 35) designed to evacuate the vacuum chamber (10), and a barrier device (40), by means of which the first cold trap device (20) can be separated from the vacuum chamber (10). A method for operating an MBE device is also described.

The invention relates to a molecular beam epitaxy device (MBE device) which is provided for the reactive deposition of a group III nitride semiconductor, and to a method for operating an MBE device, in which a group III nitride compound semiconductor is reactively deposited using ammonia.

Group III nitride compound semiconductors are used in particular for the production of light-emitting components, such as e.g. light-emitting diodes or laser diodes based on GaN. Various methods are known for depositing group III nitride compound semiconductors in layer form. In the MOCVD (“metal organic chemical vapor deposition”) method, a reactive deposition of the compound semiconductor takes place in which nitrogen is brought into contact on the substrate with a complex organic compound of the group V elements, e.g. gallium trimethyl. The MOCVD method is disadvantageous in that the vacuum conditions required during the reactive deposition are compatible only to a limited extent with standard techniques of ultrahigh vacuum technology. Important in-situ checks (such as RHEED for example) of the growth process therefore cannot be carried out.

As an alternative, group III nitride compound semiconductors can be deposited using the MBE method (molecular beam epitaxy method). In a first variant of the MBE method, molecular nitrogen is provided by means of a plasma source (radiofrequency (RF) or electron cyclotron resonance (ECR) source). However, this technique has disadvantages due to the generation of disruptive nitrogen ions and due to a relatively low growth rate. In a second variant, molecular nitrogen is provided by means of a thermal decomposition of ammonia (NH₃) (reactive molecular beam epitaxy). One problem of reactive molecular beam epitaxy is the fact that on the one hand a relatively large quantity of ammonia has to be provided for thermal decomposition on the substrate, and on the other hand excess ammonia has to be pumped off as quickly as possible in order to maintain a sufficient high vacuum. This problem is particularly critical when a high growth rate is to be achieved during the layer deposition.

Ammonia gas is pumped off using chemically resistant turbomolecular pumps. Other types of pump are less suitable for pumping ammonia due to their low suction power (ion pumps) or due to their limited chemical resistance (cryopumps). However, turbomolecular pumps also have the disadvantage that the typical suction power (e.g. 1500 l/s) is in practice not sufficient to pump the quantity of ammonia gas produced during the reactive MBE method at a sufficient chamber pressure (e.g. 5·10⁻⁵ mbar during the epitaxy process). Cold shields (cryopanels, cryoshrouds) are therefore used in order to assist the turbomolecular pump.

In commercial MBE systems, cold shields which are cooled by liquid nitrogen are used in order to bind residual gases. Attempts to freeze out the excess ammonia on cryoshields are also known from practice. Here, the problem occurred that after the epitaxy process, when the cold shields are thawed in order to release the ammonia, the frozen ammonia promptly evaporates at a certain temperature and thereby causes a considerable increase in the chamber pressure. This effect is further amplified by the heat transport of effusion cells in the MBE system towards the cold shield. The pressure may increase to the mbar range, which leads to the undesirable collapse of the turbomolecular pumps.

Due to the explosion-like increase in pressure which occurs when regenerating the cold shields in order to release the ammonia, a growth cycle during the coating of a substrate is interrupted. A continuous operation of the MBE system under practical production conditions is therefore ruled out.

The objective of the invention is to provide an improved molecular beam epitaxy device (MBE device) which avoids the disadvantages of the conventional MBE techniques and which in particular allows a reliable discharge of ammonia gas. The MBE device is intended to be suitable in particular for continuous operation. The objective of the invention is also to provide an improved method for the reactive MBE of nitride compounds, which avoids the disadvantages of the conventional techniques such as e.g. a greatly increasing basic chamber pressure during the cold shield heating phase.

These objectives are achieved by an MBE device and a method for operating an MBE device having the features of the independent claims. Advantageous embodiments and applications of the invention can be found in the dependent claims.

According to a first aspect, the invention is based on the general technical teaching of providing an MBE device which is adapted for the reactive deposition of a group III nitride compound semiconductor in a vacuum chamber (growth chamber) which is capable of being evacuated, said MBE device comprising a first cold trap device which is designed to condense ammonia and which can be separated (decoupled) from the vacuum chamber by a barrier device. The first cold trap device is intended to freeze excess ammonia out of the vacuum chamber during operation of the MBE device. In order to regenerate the first cold trap device (release the ammonia), the connection between the cold trap device and the vacuum chamber can be closed by the barrier device so that the vacuum in the vacuum chamber is maintained during the release of the ammonia from the first cold trap device, e.g. by heating the latter. An increase in pressure and thus an undesirable influencing of the MBE deposition process in the vacuum chamber is avoided.

The inventors have found that, to obtain the effect of the first cold trap device, it is advantageously not absolutely necessary for the latter to be arranged directly in the vacuum chamber. The desired condensation of the excess ammonia can also be achieved if the first cold trap device is separated from the vacuum chamber by the closable barrier device. The generation of the ammonia partial pressure makes it possible for the ammonia to be frozen out through the open barrier device into the first cold trap device. As the barrier device, use may be made of any component from vacuum technology, such as e.g. a valve or a UHV slide, by means of which a connection between the cold trap device and the vacuum chamber can be closed in a pressure-tight (vacuum-tight) manner.

According to a second aspect, the invention is based on the general technical teaching of providing a method for operating an MBE device, in particular a method for depositing a group III nitride compound semiconductor by means of reactive molecular beam epitaxy in a vacuum chamber, in which, in order to release ammonia which has condensed on a first cold trap device, the first cold trap device is separated from the vacuum chamber by a barrier device. With the actuation of the barrier device, the first cold trap device is closed in a pressure-tight manner with respect to the vacuum chamber, so that an increase in pressure in the first cold trap device is not critical to the MBE deposition process in the vacuum chamber.

It is particularly advantageous that the vacuum chamber of the MBE device can remain under ultrahigh vacuum conditions in all operating phases, in particular during the regeneration of the first cold trap device. An increase in pressure and any running-down of the molecular beam sources to room temperature during the heating of the first cold trap device in the vacuum chamber can be avoided. These advantages are particularly effective during the deposition of group III nitride compound semiconductor layers, since constant flows of the molecular beam sources and ammonia partial pressure can be achieved without impairing the operation of the MBE device. Compared to the conventional reactive MBE method, the invention allows a better reproducibility of the growth rate and an improved quality of the compound semiconductor layers.

A further advantage is the flexibility in terms of coupling the first cold trap device to the vacuum chamber. The provision of the barrier device can be adapted without any problem to the specific structure of the MBE device. By way of example, according to one preferred embodiment, the first cold trap device may comprise at least one cold trap which is arranged between the vacuum chamber and a pump device, by means of which the vacuum chamber can be evacuated. This embodiment of the invention has the particular advantage that the pump device provides a preferred direction of the flow out of the vacuum chamber, by means of which the excess ammonia is also guided towards the cold trap.

As an alternative or in addition, the first cold trap device may comprise at least one cold trap which is arranged in a supplementary vacuum chamber, which is connected to the vacuum chamber via the barrier device. This embodiment of the invention has the particular advantage that an existing MBE device can be retrofitted with little complexity by connecting the supplementary vacuum chamber to the vacuum chamber via a vacuum connection and arranging the cold trap in the supplementary vacuum chamber. The supplementary vacuum chamber is preferably connected to a vacuum pump of the pump device. It is thus possible to improve the flow from the vacuum chamber to the supplementary vacuum chamber and the collection of ammonia on the cold shield.

The pump device may comprise at least one vacuum pump which is designed to evacuate the vacuum chamber via at least one vacuum connection. As the vacuum pump, any type of pump may be used, e.g. preferably a combination of a turbomolecular pump and a fore pump. As an alternative or in addition, at least one ion pump and/or cryopump may be provided.

The first-mentioned embodiment of the invention, in which the at least one cold trap is arranged in a vacuum connection between the vacuum chamber and at least one vacuum pump, may be implemented in different variants. According to a first variant, a single cold trap is provided in a vacuum connection between the vacuum chamber and the pump device. The barrier device comprises one single barrier element which is arranged in the vacuum connection between the vacuum chamber and the cold trap. In this case, advantages are obtained due to a simple structure of the MBE device. According to a second variant, a plurality of cold traps, e.g. two cold traps, are arranged between the vacuum chamber and the pump device in a manner connected in parallel. For example, two or more vacuum connections may be provided between the vacuum chamber and the pump device, in each of which a cold trap is arranged. In this case, the barrier device comprises a plurality of barrier elements, e.g. two barrier elements. Each barrier element is assigned to one of the cold traps and is arranged between the vacuum chamber and the respective cold trap. The second variant comprising a plurality of cold traps has the particular advantage that an alternating mode of operation is possible. While one cold trap is decoupled from the vacuum chamber for the purpose of regeneration and releasing ammonia, the evacuation of the vacuum chamber can take place via the second cold trap (or further cold traps). An alternating mode of operation is achieved, which allows completely interruption-free operation of the MBE device.

Preferably, the at least one cold trap comprises a tubular baffle which is arranged between the vacuum chamber and the pump device. The baffle is cooled with liquid nitrogen in order to condense ammonia. The use of the baffle has the advantage that a large internal surface area is provided for the effective condensation of ammonia. As an alternative, the at least one cold trap comprises a cold shield which is arranged e.g. in the supplementary vacuum chamber. The cold shield is cooled with liquid nitrogen in order to condense ammonia. Advantageously, the provision of the cold shield in the supplementary vacuum chamber allows an effective collection of ammonia gas, wherein the structure of the vacuum system, in particular of the vacuum chamber and of the connection to the pump device, can remain unchanged.

According to a further advantageous embodiment of the invention, the at least one cold trap can be evacuated independently of the vacuum chamber. The at least one cold trap may be pumped off by means of a vacuum pump in particular in an operating state in which the connection to the vacuum chamber is closed by the barrier device. As a result, the discharge of the ammonia released during the heating of the cold trap is advantageously accelerated. With particular preference, the pump device of the MBE device is used to pump off the at least one cold trap. To this end, the cold trap can be pumped off directly when the barrier device is closed, e.g. using the turbomolecular pump of the pump device. As an alternative, it may be provided that the cold trap is pumped off using a fore pump of the turbomolecular pump. A collapse of the turbomolecular pump can thus advantageously be avoided.

In order to evacuate the at least one cold trap using a fore pump of the pump device, according to one particularly preferred embodiment of the MBE device according to the invention a closable bypass line is provided, via which the at least one cold trap is connected to the fore pump. In order to release ammonia from the cold trap, the barrier device, in particular the barrier element between the vacuum chamber and the cold trap, and a further barrier element between the cold trap and the turbomolecular pump are closed, while the bypass line is opened.

According to a further, particularly advantageous variant of the invention, the vacuum chamber is equipped with a second cold trap device which is designed to collect residual gas in the vacuum chamber. Advantageously, use may be made in particular of a cold trap device which is arranged in the vacuum chamber and which is present as standard in the case of commercial MBE systems. The second cold trap device preferably serves to freeze out exclusively residual gas, which contains no ammonia gas. To this end, the second cold trap device, which comprises e.g. a cold shield, is designed to operate at a temperature which is selected to be below the condensation temperature of some residual gases, such as e.g. H₂O, in the vacuum chamber and above the condensation temperature of ammonia. The second cold trap device is preferably equipped with a convection cooler, which contains as coolant e.g. alcohol or silicone oil. The temperature of the second cold trap device is selected e.g. in the range from −85° C. to −65° C.

Further details and advantages of the invention will be explained below with reference to the appended drawings, in which:

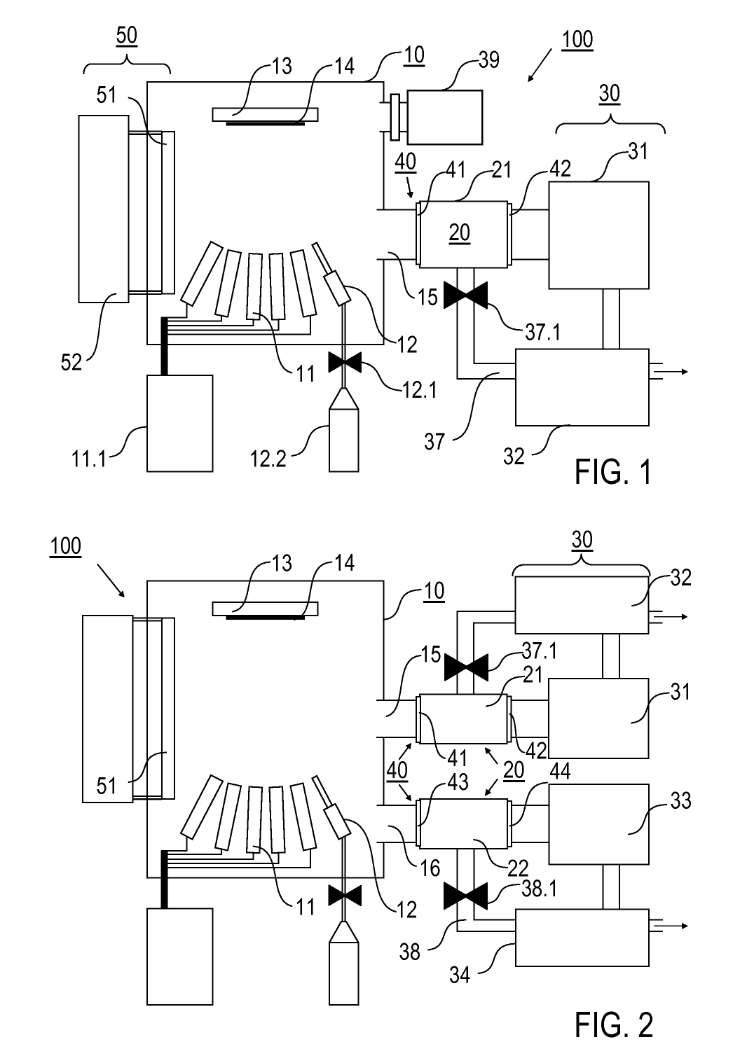

FIGS. 1 to 3 show schematic illustrations of embodiments of the MBE device according to the invention.

Embodiments of the MBE device according to the invention and of an MBE method will be explained below in particular with reference to the properties of the cold trap devices and the barrier device and the operation thereof. Details regarding the MBE device, in so far as these are known from the conventional MBE technique, such as e.g. sluices or measuring devices, will not be described. The implementation of the invention is not limited to the MBE device which is illustrated schematically (and in particular not to scale) comprising one single vacuum chamber, but rather is also possible in a corresponding manner with an MBE system as used in commercial production for uninterrupted operation to produce group III nitride compound semiconductor layers. Details regarding the reactive deposition of the compound semiconductor, in particular the choice of operating parameters, are implemented in a manner known from the conventional reactive MBE method for the deposition of crystalline nitride layers.

FIG. 1 illustrates a first embodiment of the MBE device 100 according to the invention comprising a vacuum chamber 10, a first cold trap device 20, a pump device 30, a barrier device 40 and a second cold trap device 50. In this embodiment, a single connection is provided between the vacuum chamber 10 and the pump device 30, wherein the first cold trap device 20 comprises a single cold trap 21 which is arranged between the vacuum chamber 10 and the pump device 30.

The vacuum chamber 10 comprises a recipient in which there are arranged at least one molecular beam source 11, at least one injector 12 for a reactive gas and a substrate holder with a heating system for heating the substrate 13 in order to hold a substrate 14 to be coated. For example, a plurality of molecular beam sources 11 are provided, which are connected to a source control system 11.1. The molecular beam sources 11 comprise e.g. effusion cells, as known from MBE technology. The injector 12 is connected via a metering valve 12.1 to a gas reservoir 12.2. Further components of the vacuum chamber 10, such as e.g. sluices, slides and measuring devices, are not shown.

Additionally arranged in the vacuum chamber 10 is the second cold trap device 50 comprising at least one cold shield 51 (cryoshroud), which is connected to a convection cooler 52. The at least one cold shield 51 is constructed in the manner known from conventional MBE devices. Preferably, the cold shield 51 is arranged on at least one of the walls of the vacuum chamber 10. The operating temperature of the cold shield 51 is preferably selected in the range from −85° C. to −65° C., e.g. −75° C. This temperature is selected in particular as a function of the vacuum chamber pressure during the reactive epitaxy process, wherein it is derived from the condensation point of the ammonia gas, which is dependent on the partial pressure of the ammonia gas. The operating temperature of the second cold trap device (cold shield) is therefore higher than the condensation temperature of the ammonia gas under the given operating conditions of the vacuum chamber 10.

The vacuum chamber 10 is connected to the pump device 30 via a vacuum connection 15. The vacuum connection 15 comprises e.g. a combination of a flange and a pipeline. The pump device 30 comprises as the main pump a turbomolecular pump 31, which is equipped with a fore pump 32. The first cold trap device 20 comprises a cold trap in the form of a tubular baffle 21 with internal cooling surfaces, which is installed in the vacuum connection 15. The baffle 21 is cooled with liquid nitrogen by means of a circulating cryostat (not shown). The baffle 21 is dimensioned as a function of parameters relating to the method and vacuum technology, in particular as a function of the quantity of ammonia to be condensed and the suction power of the pump device 30. Furthermore, the vacuum chamber 10 is connected to an additional UHV pump 39 (e.g. an ion getter pump or turbopump) via a vacuum connection which can be closed by a valve.

On the side facing towards the vacuum chamber 10, a valve 41 is provided as a barrier element of the barrier device 40, by means of which the flow path from the vacuum chamber 10 to the baffle 21 can be closed in a vacuum-tight manner. The valve 41 comprises e.g. a UHV slide. On the side facing towards the pump device 30, the baffle 21 is equipped with a further barrier element which likewise comprises a valve 42. The baffle 21 is connected to the fore pump 32 of the pump device 30 via a bypass line 37. A bypass valve 38 is arranged in the bypass line 37.

Operation of the MBE device 100 comprises the following steps. Firstly, after the molecular beam sources 11 have been charged, an evacuation of the vacuum chamber 10 takes place. To this end, the valves 41, 42 are opened, while the bypass valve 38 is closed. The evacuation of the vacuum chamber 10 takes place by means of the turbomolecular pump 31 in combination with the fore pump 32. The charging and evacuation take place according to generally customary standard procedures for MBE systems and UHV chambers. After the evacuation, a (pre-treated) substrate 14 can be placed on the substrate holder, as known from conventional reactive MBE methods. The treatment of the substrate 14 comprises e.g. the previous desorption of H₂O and/or a sputtering onto the rear side, which is intended to improve the thermal coupling during the reactive deposition of the compound semiconductor, particularly if the substrate is thermally transparent.

Then, for the reactive layer deposition, at least one molecular beam is generated from at least one of the molecular beam sources 11 and ammonia is injected into the vacuum chamber 10. By way of example, a GaN layer is deposited on the substrate 14. Prior to the deposition process, the UHV pump 39 can be separated from the vacuum chamber 10 by means of the valve. During the deposition of the compound semiconductor, operation of the pump device 30 continues. With the residual gas which is pumped out of the vacuum chamber 10 via the vacuum connection 13, ammonia gas is also transported away. The ammonia gas is condensed on the baffle 21 of the cold trap device 20. In experiments, one particular advantage of the invention was the fact that the ammonia is pumped particularly effectively onto the liquid-nitrogen-cooled cooling surface of the baffle 21, so that the pump power is increased by a factor of 10 (relative to a non-cooled baffle).

During the coating process, which may last for example for a few hours, ammonia continuously precipitates in the baffle 21. In order to regenerate the internal cooling surfaces of the baffle 21, the following steps are provided. Firstly, the baffle 21 is separated from the vacuum chamber 10 by closing the valve 41. Before this, the UHV pump 39 is connected to the vacuum chamber 10. The cooling of the baffle 21 is switched off, so that heating takes place. The frozen ammonia is transformed into the gaseous state as the temperature increases. The ammonia gas is pumped off by the turbomolecular pump 31. If the quantity of ammonia gas is too large for the suction power of the turbomolecular pump 31, the valve 42 is closed and the bypass valve 37.1 is opened. In this state, the baffle 21 is pumped off by means of the fore pump 32 via the bypass line 37. As soon as a sufficiently low pressure is reached in the baffle 21, the bypass valve 37.1 can be closed. The further pumping until an ultrahigh vacuum is obtained then takes place by means of the turbomolecular pump 31. Finally, the valve 41 is opened again in order to evacuate the vacuum chamber 10 during the further operation of the MBE device. Advantageously, the release of the ammonia from the baffle 21 may take place over a relatively long time period of e.g. 12 h (temperature increase from 77 K to 300 K), since the external application of heat to the baffle 21 is extremely low, wherein a sufficient ultrahigh vacuum can be maintained in the vacuum chamber 10 by the UHV pump 39. With the embodiment according to FIG. 1, therefore, already a normal workday operation (e.g. 8 to 12 h operation) of the MBE device 100 can be achieved, in particular without interrupting the growth cycle of the MBE deposition during normal operating times.

A further embodiment of the MBE device 100 according to the invention, which is shown in FIG. 2, comprises in addition to the structure described above a further turbomolecular pump 33 with a fore pump 34, which are connected to the vacuum chamber 10 via a further vacuum connection 16. A further cold trap of the cold trap device 20 is arranged in the vacuum connection 16. The cold trap comprises a further baffle 22, which on the side facing towards the vacuum chamber 10 can be closed by a further barrier element, comprising a valve 43. Also provided is a valve 44 for decoupling the baffle 22 from the turbomolecular pump 33, and a second bypass line 38 with a second bypass valve 38.1 as a bypass between the baffle 22 and the fore pump 34. In the embodiment shown in FIG. 2, the additional UHV pump 39 shown in FIG. 1 is not provided. However, an additional UHV pump may be provided, depending on the intended operation of the MBE device 100.

The operation of the MBE device 100 shown in FIG. 2 takes place in the manner described above and in particular with reference to FIG. 1. Due to the double design of the combination of vacuum pumps and cold traps, a 24 h continuous operation (production of compound semiconductors) of the vacuum chamber 10 can be ensured, even when one of the baffles 21, 22 is heated and evacuated in order to release the ammonia in the decoupled state.

By way of example, it may be provided that firstly the baffle 21 is regenerated. While the valves 43, 44 of the second baffle 22 remain open and the evacuation of the vacuum chamber 10 takes place by means of the turbomolecular pump 33, the first baffle 21 is decoupled from the vacuum chamber 10 and the turbomolecular pump 31 by means of the valves 41, 42 and is evacuated via the bypass line 37. After the ammonia has been released from the baffle 21, the latter can again be connected to the vacuum chamber 10. The regeneration of the second baffle 22 may then take place by correspondingly closing the valves 43, 44 and evacuating the baffle 22 by means of the fore pump 34 and/or the turbomolecular pump 33.

The embodiment of the invention shown in FIG. 2 can be modified so that the pump device 30 comprises one single vacuum pump 31 (with a fore pump 32), to which the baffles 21, 22 can be jointly connected via valves 42, 44 which can be actuated separately.

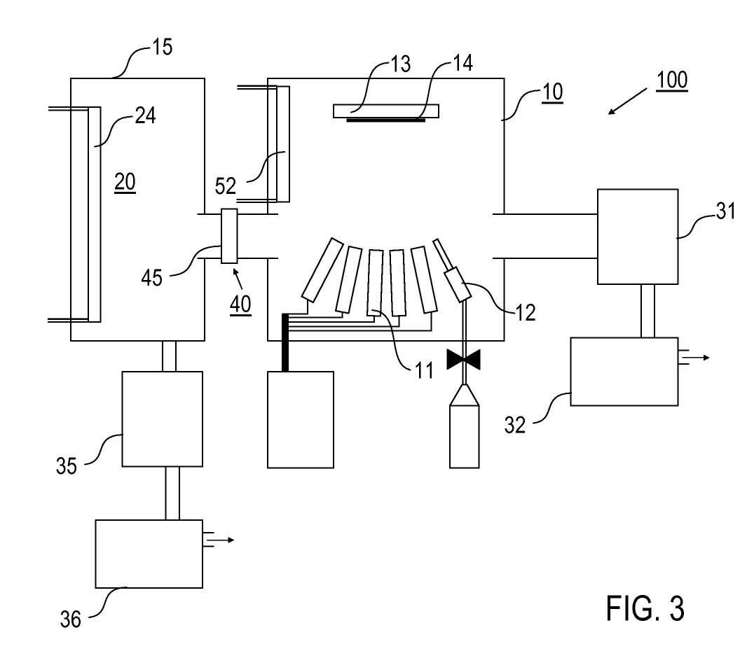

FIG. 3 illustrates by way of example the further embodiment of the MBE device 100 according to the invention. In this case, the turbomolecular pump 31 with the fore pump 32 is connected to the vacuum chamber 10 via a vacuum connection 15, as is known from conventional MBE devices. The vacuum chamber 10 is connected via a vacuum connection 17 to a supplementary vacuum chamber 15, in which at least one cold shield 23 is arranged as the cold trap of the cold trap device 20. The vacuum chamber 10 and the supplementary vacuum chamber 15 are coupled via the vacuum connection 17, in which the barrier device 40 is provided. As the barrier element, a vacuum-tight valve 45 is provided in the vacuum connection 17. The supplementary vacuum chamber 15 can be evacuated by a further combination of a turbomolecular pump 35 and a fore pump 36.

The operation of the MBE device 100 shown in FIG. 3 takes place in essentially the same way as described above with reference to FIG. 1. During the deposition of the compound semiconductor, continuous operation of the turbomolecular pump 33 takes place, by means of which excess ammonia is sucked into the supplementary vacuum chamber 15. In the latter, the ammonia condenses on the cold shield 23 which is cooled with liquid nitrogen. In order to regenerate the cold shield 23, the valve 45 is closed so that the cold trap device 20 is decoupled from the vacuum chamber 10. In this state, a heating of the cold shield 23 takes place and the supplementary vacuum chamber 15 is evacuated by means of the turbomolecular pump 33. After the freed ammonia gas has been pumped off, the valve 45 is opened for further operation of the MBE device 100.

The features of the embodiment of the MBE device according to the invention shown in FIGS. 1 to 3 can be combined with one another. By way of example, one or more cold traps as a baffle between the vacuum chamber 10 and the pump device 30 can be combined with one or more cold shields in one or more supplementary vacuum chambers 15.

The features disclosed in the description, the claims and the drawings may be important both individually and in combination for implementing the invention.

1-20. (canceled)

21. A molecular beam epitaxy device (MBE device) which is adapted for the reactive deposition of a group III nitride compound semiconductor, comprising:
a vacuum chamber which comprises at least one molecular beam source and at least one injector designed to inject ammonia into the vacuum chamber,
a first cold trap device comprising at least one cold trap designed to condense excess ammonia,
a pump device comprising at least one pump designed to evacuate the vacuum chamber, and
a barrier device, by means of which the first cold trap device can be separated from the vacuum chamber.

22. The MBE device according to claim 21, in which
the first cold trap device comprises a cold trap which is arranged between the vacuum chamber and the pump device, wherein
the barrier device comprises a barrier element which is arranged between the vacuum chamber and the cold trap.

23. The MBE device according to claim 22, in which
the first cold trap device comprises at least two cold traps which are arranged in separate vacuum connections between the vacuum chamber and the pump device, wherein
the barrier device comprises at least two barrier elements which are arranged in each case between the vacuum chamber and the cold traps.

24. The MBE device according to claim 23, in which
the at least two cold traps are configured in such a way that, when one of the cold traps is separated from the vacuum chamber by the barrier device, the respective other cold trap is connected to the vacuum chamber, and wherein
the cold trap separated from the vacuum chamber in each case is designed to release condensed ammonia.

25. The MBE device according to claim 21, in which
the at least one cold trap comprises a tubular baffle which is arranged accordingly in a vacuum connection between the vacuum chamber and a pump of the pump device.

26. The MBE device according to claim 21, in which
the at least one cold trap comprises a cold shield which is arranged in a supplementary vacuum chamber, wherein
the barrier device comprises a barrier element which is arranged between the vacuum chamber and the supplementary vacuum chamber.

27. The MBE device according to claim 21, in which
the at least one cold trap can be evacuated separately from the vacuum chamber.

28. The MBE device according to claim 27, in which
the at least one cold trap can be evacuated by means of the pump device.

29. The MBE device according to claim 28, in which
the at least one cold trap can be evacuated by means of at least one fore pump of the pump device.

30. The MBE device according to claim 29, in which
the at least one cold trap is connected to the at least one fore pump via a closable bypass line.

31. The MBE device according to claim 21, which comprises:
a second cold trap device which is designed to condense residual gas in the vacuum chamber.

32. The MBE device according to claim 31, in which
the second cold trap device comprises a cold shield which is arranged in the vacuum chamber.

33. The MBE device according to claim 31, in which
the second cold trap device is designed for an operating temperature at which ammonia under vacuum conditions remains in the gaseous state and residual gas in the vacuum chamber condenses.

34. Method for operating an MBE device, comprising the steps:
evacuating a vacuum chamber of the MBE device by means of a pump device,
generating a molecular beam of a group III element in the vacuum chamber,
injecting ammonia into the vacuum chamber, and
reactively depositing a group III nitride compound semiconductor on a substrate in the vacuum chamber, wherein
ammonia, which makes no contribution to the reactive deposition, is condensed on a first cold trap device, and
the ammonia flows from the vacuum chamber to the first cold trap device through a closable barrier device, by means of which the first cold trap device can be separated from the vacuum chamber.

35. Method according to claim 34, comprising the steps
closing the barrier device, and
releasing condensed ammonia from the first cold trap device, wherein, during the release from the first cold trap device, a high vacuum is maintained in the interior of the vacuum chamber.

36. Method according to claim 35, in which
the first cold trap device is heated and evacuated in order to release the ammonia.

37. Method according to claim 36, in which
the first cold trap device is evacuated by means of the pump device.

38. Method according to claim 34, in which
the first cold trap device comprises at least two cold traps which are arranged in separate vacuum connections between the vacuum chamber and the pump device, wherein
during the release of the condensed ammonia from one of the cold traps, the condensation of ammonia from the vacuum chamber takes place in each case in one of the other cold traps.

39. Method according to claim 36, comprising the step:
condensing residual gas on a second cold trap device in the vacuum chamber.

40. Method according to claim 39, in which
the second cold trap device is operated at a higher operating temperature than the first cold trap device, so that no ammonia condenses on the second cold trap device.
